(19) United States
(12) Patent Application Publication
(10) Pub. No.: US 2012/0222813 A1
(43) Pub. Date: Sep. 6, 2012

(54) VACUUM CHAMBERS WITH SHARED PUMP

(75) Inventors: Aniruddha Pal, Santa Clara, CA (US); Martin Jeffrey Salinas, Campbell, CA (US); Jared Ahmad Lee, Santa Clara, CA (US); Paul B. Reuter, Austin, TX (US); Imad Yousif, San Jose, CA (US)

(73) Assignee: APPLIED MATERIALS, INC., Santa Clara, CA (US)

(21) Appl. No.: 13/408,810

(22) Filed: Feb. 29, 2012

Related U.S. Application Data
(60) Provisional application No. 61/448,024, filed on Mar. 1, 2011.

(51) Int. Cl. C23C 16/455; B05C 11/00; C23C 16/50; B05C 5/02; B05B 1/18

(52) U.S. Cl. 156/345.31; 118/719; 156/345.1; 156/345.34; 156/345.35; 156/345.52

(57) ABSTRACT

Embodiments of the present disclosure generally relate to vacuum processing chambers having different pumping requirements and connected to a shared pumping system through a single foreline. In one embodiment, the vacuum processing chambers include a high conductance pumping conduit and a low conductance pumping conduit coupled to a single high conductance foreline. In another embodiment, a plurality of unbalanced chamber groups may be connected to a common pumping system by a final foreline.

### CROSS-REFERENCE TO RELATED APPLICATIONS

This application claims benefit of U.S. Provisional Patent Application Ser. No. 61/448,024, filed Mar. 1, 2011, which is herein incorporated by reference.

### BACKGROUND

1. Field

Embodiments of the present disclosure generally relate to vacuum chambers having different pumping requirements coupled to a pumping system through a single foreline.

2. Description of the Related Art

In vacuum processing tools such as those used to fabricate integrated circuits, flat panel displays, and magnetic media among others, a vacuum environment is maintained in the chambers of the vacuum processing tools through the use of a vacuum pump. Since the processes performed in the various vacuum processing chambers have different pressure and/or pumping requirements, each vacuum processing chamber typically has a dedicated vacuum pump. Thus, vacuum pumps are only conventionally shared between vacuum chambers having identical pumping requirements due to the inability to precisely meet pumping requirements which are unique to different environments. The need for dedicated pumps for each vacuum chamber increases the overall cost of the system, as well as hardware costs and costs associated with the extra space requirements for multiple pumps.

Therefore, there is a need for an improved processing system with the capability to a single vacuum pump to service vacuum processing regions having different pumping requirements.

### SUMMARY

The present disclosure generally relates to vacuum chambers for processing substrates. The vacuum chambers include a first substrate chamber isolated from a second substrate chamber, a vacuum pump, and a high conductance foreline coupled to the pump. A high conductance pumping conduit couples the foreline to the first substrate chamber and a low conductance pumping conduit coupling the foreline to the second substrate chamber. The conductance of each conduit is selected to allow different pumping requirements of each chamber to be met using a single pump (or pumps) coupled to a single foreline.

Another embodiment of the present disclosure provides a chamber body having first and second substrate transfer chambers. The first substrate transfer chamber is isolated from the second substrate transfer chamber. The substrate transfer chambers further include a vacuum pump and a high conductance foreline coupled to the pump. A high conductance pumping conduit couples the foreline to the first substrate transfer chamber, and a low conductance pumping conduit couples the foreline to the second substrate transfer chamber.

Another embodiment of the present disclosure provides a system having a first chamber body having a first substrate transfer chamber isolated from a second first substrate transfer chamber and a second chamber body having a third substrate transfer chamber isolated from a fourth first substrate transfer chamber. The system also includes a vacuum pump, a high conductance foreline coupled to the pump, a first high conductance pumping conduit coupling the high conductance foreline to the first substrate transfer chamber, and a second high conductance pumping conduit coupling the high conductance foreline to the third substrate transfer chamber. The system further includes a low conductance foreline coupled to the high conductance foreline, a first low conductance pumping conduit coupling the low conductance foreline to the second substrate transfer chamber, and a second low conductance pumping conduit coupling the low conductance foreline to the fourth substrate transfer chamber.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a front sectional view of a vacuum chamber according to one embodiment of the disclosure.

FIG. 2 is a schematic sectional view of the vacuum chamber of FIG. 1.

FIG. 3 is another sectional plan view of the vacuum chamber of FIG. 1.

FIG. 4 is a schematic view of a vacuum chamber having a pump system according to an embodiment of the disclosure.

FIG. 5 is a partial schematic diagram of an alternative embodiment of the pump system of FIG. 4.

FIG. 6 is a front schematic view of one embodiment having multiple vacuum chambers and one pump system.

FIG. 7 is a front schematic view of an alternative embodiment having multiple vacuum chambers and one pump system.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure provides a substrate vacuum processing system that includes a plurality of substrate chambers isolated from each other. The substrate chambers are each coupled to a vacuum pump by pumping conduits configured to have a ratio of conductance selected so that the substrate chambers may share a common vacuum pump.

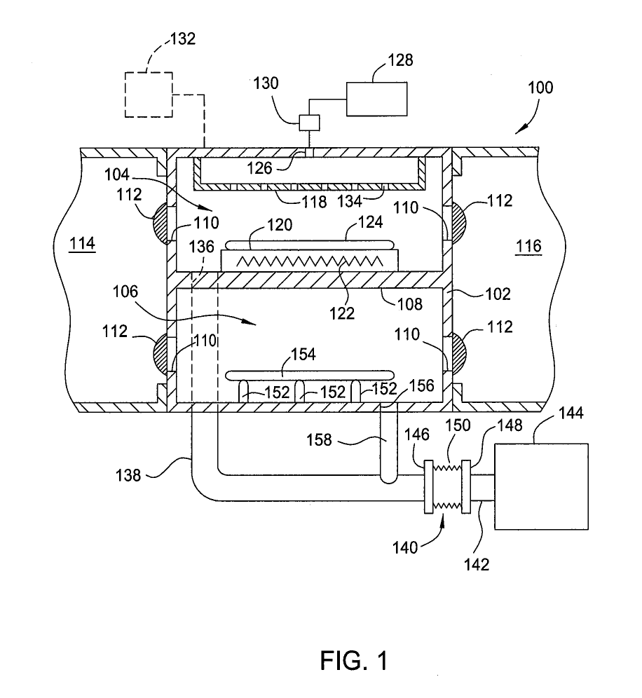

FIG. 1 is a front sectional view of a processing system 100 according to one embodiment of the disclosure. The processing system 100 generally includes a chamber body 102 having a first chamber 104 isolated from a second chamber 106 by an internal wall 108. Although the chambers 104, 106 are illustrated in a common chamber body 102, the chambers 104, 106 may alternatively be disposed in separate bodies. Substrate transfer ports 110 formed through the chamber body 102 provide access to the first and second chambers 104, 106. Doors 112 coupled to the chamber body 102 operate to selectively open and close each substrate transfer port 110 to facilitate entry and egress of substrates from the first and second chambers 104, 106. A factory interface 114 is coupled to one side of the chamber body 102. A transfer chamber 116 is coupled to another side of the chamber body 102. Although not shown, a plurality of processing chambers are coupled to the transfer chamber 116 to process the substrate.

In one embodiment, the first chamber 104 is a plasma processing chamber, such as a plasma abatement, annealing, implant, ashing or chamber of other plasma processing chamber. The first chamber 104 includes a showerhead 118, a substrate support 120, and a heater 122. During processing, the heater 122 heats a substrate 124 supported in the first chamber 104 by the substrate support 120. A gas panel 128 controls the flow of process gases through a remote plasma source 130 and into the first chamber 104 through a gas inlet 126 formed through the chamber body 120. The process gases entering into the first chamber 104 through the gas inlet 126 are distributed laterally through a plurality of apertures 134 formed through the showerhead 118 to evenly distribute process gases across the surface of the substrate 124. A RF power source 132 may be provided to power one or both of the showerhead 118 and/or substrate supports 120 to energize the gases within the first chamber 104.

A first exhaust port 136 is formed through the chamber body 102 to allow process gases to be removed from the first chamber 104. A first exhaust conduit 138 couples the first exhaust port 136 to a foreline 142. The foreline is coupled to a pumping system 144. The pumping system 144 may include one or more pumps. In the embodiment depicted in FIG. 1, an expandable coupling 140 couples the first exhaust conduit 138 to the foreline 142 to allow for thermal expansion and greater tolerances. The expandable coupling 140 generally includes bellow 150 and flanges 146, 148. The flanges 146 and 148 are sealingly coupled to the first exhaust conduit 138 and the foreline 142, respectively. The bellows 150 are sealingly coupled to the flanges 146, 148 while allowing relative motion therebetween without compromising the seal.

In the embodiment shown, the second chamber 106 is configured as a load lock chamber without plasma processing capabilities, for example, used to simply transfer substrates between vacuum and atmospheric environments of adjoining chambers and/or factory interface. The second chamber 106 may optionally have non-plasma heating and/or cooling elements (not shown). The second chamber 106 generally includes a plurality of substrate supports 152 configured to support a substrate 154 within the second chamber 106. A second exhaust port 156 is formed through the chamber body 102 and is coupled to a second exhaust conduit 156. The second exhaust conduit 15 is coupled to the foreline 142 and ultimately the pump 144 by a flexible coupling 140. The first exhaust conduit 138 and second exhaust conduit 158 are configured to each have a different predetermined conductance such that the pumping requirements of first and second chambers 104, 106 may be served by a single pumping system 144. As shown in FIG. 1, the first exhaust conduit 138 is configured to have a high conductance to permit a larger volume of gases to be removed from the first chamber 104 as necessitated by the plasma processes performed therein. The second exhaust conduit 158 is configured to have a low conductance relative to the conductance of the first exhaust conduit 138, such that the different rates of gases pumped from the first and second chambers 104, 106 may be simultaneously pulled through a single foreline 142 by a single pumping system 144.

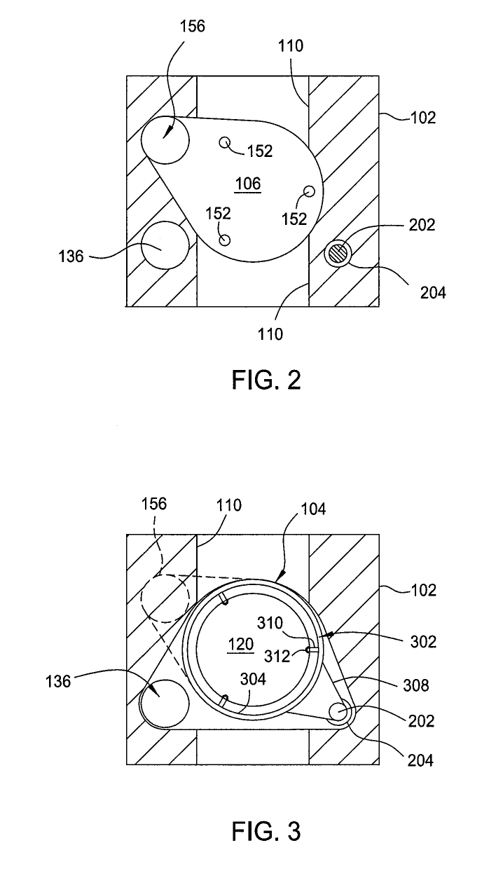

FIG. 2 is a sectional view of the chamber body 132 through the second chamber 106. As described above, the second exhaust port 156 is fluidly coupled to the second chamber 106. Additionally, the first exhaust port 136 is formed through the chamber body 102, and is isolated from the second chamber 106 and second exhaust port 156. A hole 204 is formed through the chamber body 102, isolated from the second chamber 106, and extends into the first chamber 104 (not shown in FIG. 2). A shaft 202 is disposed within the hole 204 to control the elevation of a lift assembly as further described below.

FIG. 3 is a sectional view of the chamber body 102 through the first chamber 104. Disposed in the first chamber 104 is a lift assembly 302. The lift assembly 302 includes a hoop 304 coupled to the shaft 202 by a bracket 308. The lift assembly 302 further includes a plurality of fingers 310 extending radially inward from the hoop 304. The fingers 310 are spaced below the hoop 310 to allow a robot (not shown) to pick and place a substrate on the fingers 310. The plurality of fingers 310 align with a plurality of notches 312 formed in the substrate support 120. The fingers 310 set a substrate disposed thereon onto the substrate support 120 as the lift assembly 302 is lowered by an actuator (not shown) coupled to the shaft 202. While the fingers 310 are in the lowered position, the substrate rests on the substrate support 120 clear of the fingers 310. The hoop 304 may be elevated such that the fingers 310 lift the substrate from the substrate support 120 to an elevation aligned with the ports 110 to facilitate robotic substrate transfer.

As shown in FIG. 3, the first exhaust port 136 is fluidly coupled to the first chamber 104. The second exhaust port 156, shown in phantom, is formed through the chamber body 102 such that the port is isolated from the first chamber 104 and the first exhaust port 136.

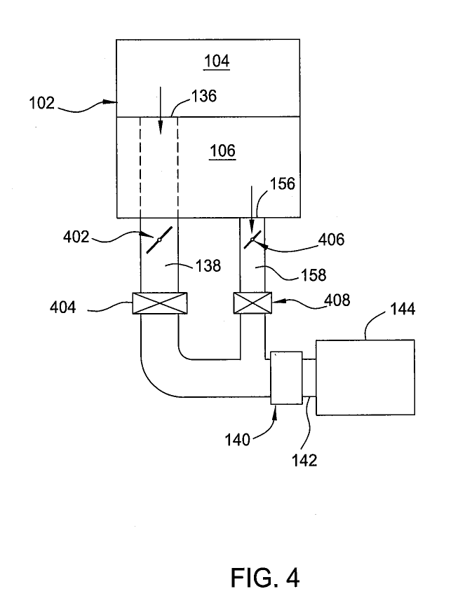

FIG. 4 is a schematic view of the chamber body 102 according to an embodiment of the disclosure. The chamber body 102 includes the first and second chambers 104, 106 coupled to the pump 144 through exhaust conduits 138, 158, respectively. Gas flow through the exhaust conduits 138, 158 may be controlled by valves disposed within the exhaust conduits. As shown in FIG. 4, a throttle valve 402 is disposed within the first exhaust conduit 138 to selectively increase or decrease the flow of gases out of the first chamber 104 and through the first exhaust conduit 138. An isolation valve 404 is disposed downstream of the throttle valve 402 to selectively close flow through the first exhaust conduit 138 and isolate the first chamber 104 (from the foreline 142 and pump 144 when required). Similarly, a throttle valve 406 is disposed within the second exhaust conduit 138 to selectively control the flow of gases from the second chamber 106. An isolation valve 408 is disposed downstream of the throttle valve 406 to isolate the second chamber 106 (from the foreline 142 and pump 144 when required).

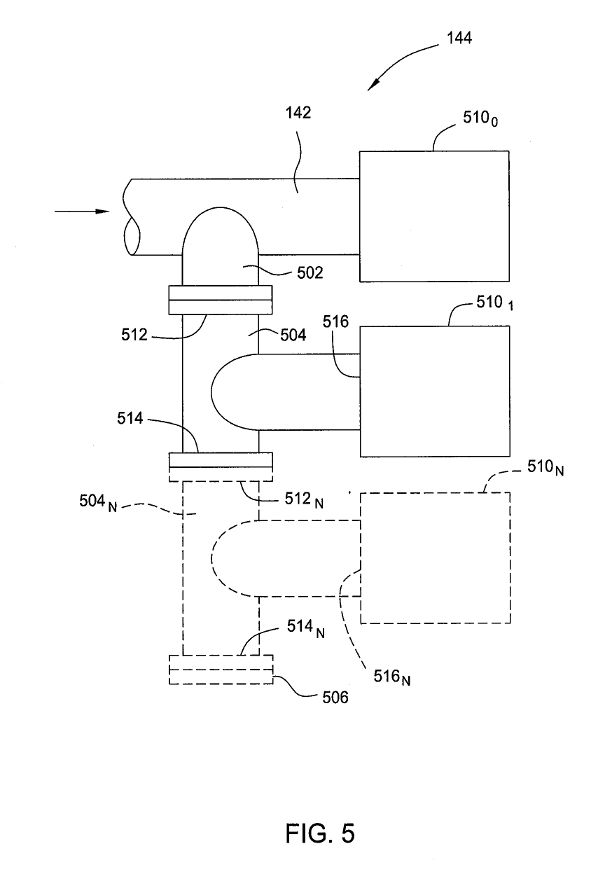

FIG. 5 is a partial schematic diagram of an alternative embodiment of the pumping system 144 described above as having one or more pumps. The pumping system 144 depicted in FIG. 5 includes a plurality of pumps coupled in parallel to the foreline 142. The pumping system 144 includes a first pump 510 coupled to the foreline 142. A second pump 510₁ is fluidly coupled to the foreline 142 by a connector 504. The connector 504 includes a first end 112 coupled to a tee 502 of the foreline 142, a second end 514 optionally coupled to an additional connector (shown in phantom as 504_{N}), and a third end 516 coupled to the second pump 510₁. It is understood that one or more additional pumps (shown in phantom as 510_{N}) may be joined using one or more connectors 504_{N} having first ends 512_{N} connected to other second ends 514_{N}, and third ends 516_{N}. An end cap 506 coupled to the second end 514_{N} of the last of the connectors 504_{N} to terminate a string of connectors 504_{N}.

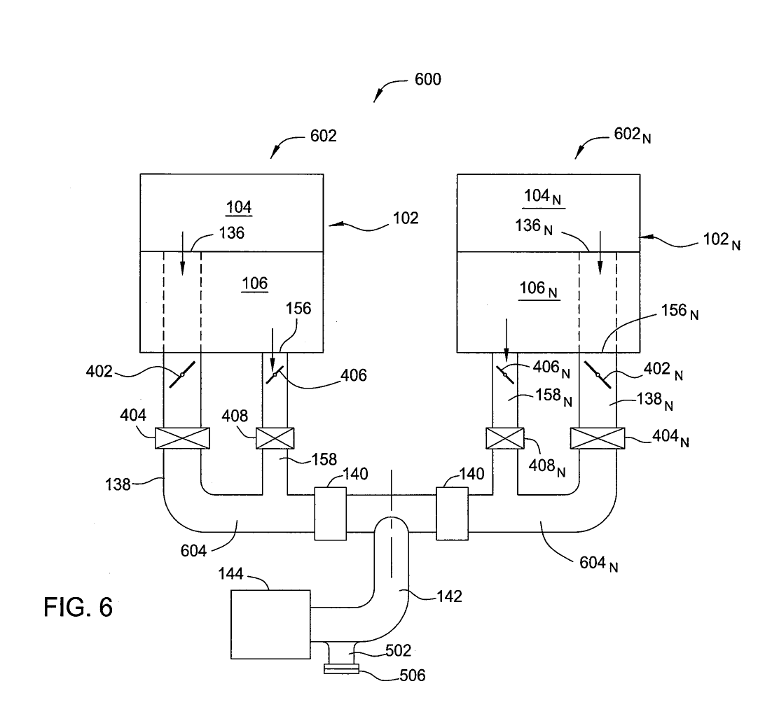

FIG. 6 is a front schematic view of a system 600 having multiple chambers serviced by pumping one system 144. The system 600 generally includes a plurality of unbalanced chamber groups 602, . . . , 602_{N}, connected to the pumping system 144 by a final foreline 142. Each unbalanced chamber group includes at least two vacuum chambers, each having different pumping requirements. To enable all the groups 602, 602_{N} of chambers to be coupled to a single final foreline 142, the conductance of each common exhaust 604, 604_{N} coupled to the exhaust conduit of the individual chambers is selected to accommodate the different flow requirements of each chamber group ultimately coupled to the common foreline 142. In one embodiment, two unbalanced groups 602, 602_{N} may have respective exhaust conduits 138, 158 and 138_{N}, 158_{N} coupled to the common exhaust 604 and 604_{N}. Each common exhaust 604 and 604_{N} is coupled to the common foreline 142. In one embodiment, the conductance of the respective conduit pairs 138, 138_{N}, 158, 158_{N} and exhaust 604, 604_{N} are equal. For example, the total conductance of exhaust conduits 138, 158 is equal to the conductance of common exhaust conduit 604. Similarly, the total conductance of exhaust conduits 138_{N}, 158_{N} is equal to the conductance of the common exhaust conduit 604_{N}. Alternatively, the conductance of the exhausts 604, 604_{N} may be different and selected to balance the pumping requirements to enable use of one or more pumps of the pumping system 144 coupled to the single final foreline 142 to serve at least two chambers.

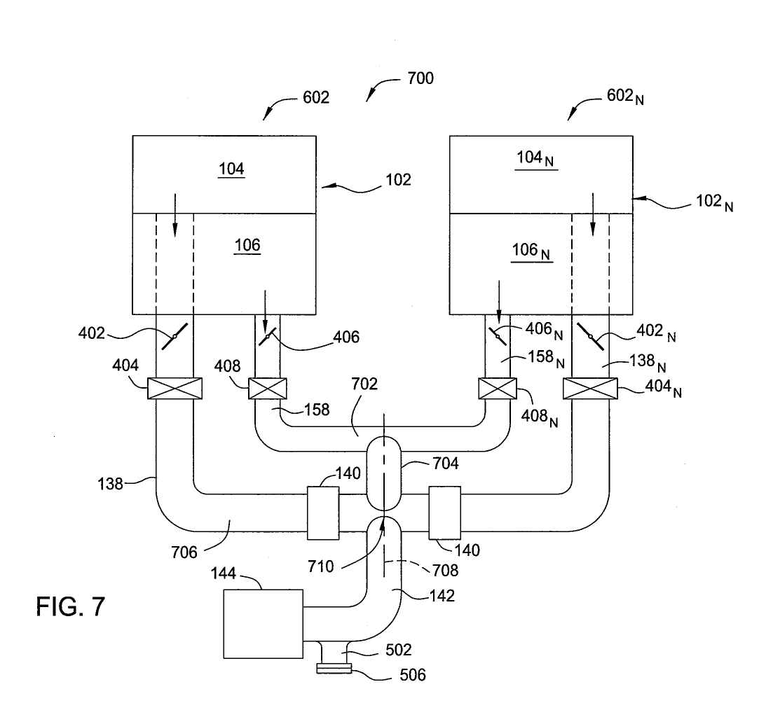

FIG. 7 depicts another embodiment of a system 700 having multiple chambers serviced by one pumping system 144. The system 700 is substantially similar to the system 600 described above except wherein each high conductance exhaust conduit 138, 138_{N} is coupled to a common high conductance common exhaust 706 which is, in turn, coupled to the pumping system 144 by the foreline 142, and the low conductance exhaust conduit 158, 158_{N} are coupled to a common low conductance exhaust 702. The low conductance exhaust 702 is coupled by a ridging line 704 to one of the high conductance common exhaust 706 or directly to the foreline 142. In one embodiment, the connection between at least one or both of the ridging conduit 704 and the foreline 142 symmetrically divides the common exhaust 702, 706 so that the exhaust passed between the chambers 104, 104_{N}, 106, 106_{N} are symmetrically balanced relative to a symmetry line 708 defined through the intersection of the foreline 142 and the high conductance common exhaust 706.

The present disclosure provides a processing system having a pump system that is advantageously modular. It is contemplated one may use one or more pumps in a pumping system coupled to a single foreline to serve at least two chambers having different pumping requirements. The use of a single foreline to serve all chambers advantageously reduces the cost and complexity of the system and provides for a smaller footprint. The system balances conductance between different chambers high low conductance conduits connect to a single foreline to allow different processes and functions to be performed in the chambers with minimal cost and space impact. Moreover, the exhaust conduits and foreline having a high conductance conduit is confined below the aerial extent of the chamber body to maintain small foot print.

While the foregoing is directed to embodiments of the present disclosure, other and further embodiments of the disclosure may be devised without departing from the basic scope thereof, and the scope thereof is determined by the claims that follow.

1. A system for processing substrates, comprising:
a chamber body having a first substrate transfer chamber isolated from a second substrate transfer chamber;
a vacuum pump;
a high conductance foreline coupled to the pump;
a high conductance pumping conduit coupling the foreline to the first substrate transfer chamber; and
a low conductance pumping conduit coupling the foreline to the second substrate transfer chamber.

2. The system of claim 1, further comprising: a second vacuum pump coupled to the high conductance foreline.

3. The system of claim 1, wherein each substrate transfer chamber has two substrate transfer ports.

4. The system of claim 1, further comprising: a showerhead disposed within the first substrate transfer chamber.

5. The system of claim 1, further comprising:
a substrate support disposed within the first substrate transfer chamber; and
a heater configured to heat the substrate support.

6. The system of claim 1, wherein the first substrate transfer chamber is coupled to a remote plasma source.

7. A system for processing substrates, comprising:
a chamber body having a first substrate transfer chamber and a second substrate transfer chamber formed therein, wherein the first substrate transfer chamber is isolated from the second substrate transfer chamber;
a vacuum pump;
a high conductance foreline coupled to the pump;
a high conductance pumping conduit coupling the foreline to the first substrate transfer chamber; and
a low conductance pumping conduit coupling the foreline to the second substrate transfer chamber.

8. The system of claim 7, wherein each substrate transfer chamber has two substrate transfer ports.

9. The system of claim 7, further comprising: a showerhead disposed within the first substrate transfer chamber.

10. The system of claim 7, further comprising:
a substrate support disposed within the first substrate transfer chamber; and
a heater configured to heat the substrate support.

11. The system of claim 7, further comprising: a second vacuum pump coupled to the high conductance foreline.

12. The system of claim 7, wherein the first substrate transfer chamber is coupled to a remote plasma source.

13. A system for processing substrates, comprising:
a first chamber body having a first substrate transfer chamber isolated from a second first substrate transfer chamber;
a second chamber body having a third substrate transfer chamber isolated from a fourth first substrate transfer chamber;
a vacuum pump;
a high conductance common exhaust coupled to the pump;
a high conductance common exhaust coupled to the high conductance foreline;
a first high conductance pumping conduit coupling the high conductance common exhaust to the first substrate transfer chamber;
a second high conductance pumping conduit coupling the high conductance common exhaust to the third substrate transfer chamber;
a low conductance common exhaust coupled to the high conductance foreline;
a first low conductance pumping conduit coupling the low conductance common exhaust to the second substrate transfer chamber; and
a second low conductance pumping conduit coupling the low conductance common exhaust to the fourth substrate transfer chamber.

14. The system of claim 13, wherein first and second high conductance pumping conduits have equal conductance.

15. The system of claim 13, wherein first and second high conductance pumping conduits are arranged in a mirror image.

16. The system of claim 13, wherein first substrate transfer chamber is a plasma processing chamber and the second substrate transfer chamber is a load lock chamber.

17. The system of claim 13, further comprising a second pump coupled to the high conductance foreline.

18. The system of claim 13, wherein the high conductance pumping conduits are coupled to the high conductance foreline by a bellows.

19. The system of claim 13, wherein each substrate transfer chamber has two substrate transfer ports.

20. The system of claim 14, wherein the first substrate transfer chamber has a substrate support heater and is coupled to a remote plasma source.
